(19) United States
(12) Patent Application Publication
(10) Pub. No.: US 2006/0099389 A1
(43) Pub. Date: May 11, 2006

(54) Droplet ejection method, electro-optic device manufacturing method, and electronic instrument

(75) Inventor: Nobuaki Nagae, Chino (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/258,344

(22) Filed: Oct. 25, 2005

(30) Foreign Application Priority Data
Nov. 8, 2004 (JP) 2004-323659
Aug. 12, 2005 (JP) 2005-234377

(51) Int. Cl. B41M 5/00

(52) U.S. Cl. 428/195.1; 427/256; 427/64

(57) ABSTRACT

A droplet ejection method of ejecting a droplet on a substrate includes: ejecting the droplet on a drawing target region surrounded by a bank formed on the substrate, in a predetermined ejecting interval while scanning an ejection head; and ejecting no droplet on a non-ejection area while scanning the ejection head. The non-ejection area is located on the drawing target region except for a region along the bank in the drawing target region.

### BACKGROUND OF THE INVENTION

1. Field of the Invention

The present invention relates to a droplet ejection method, an electro-optic device manufacturing method, and an electronic instrument.

Priority is claimed on Japanese Patent Application No. 2004-323659, filed Nov. 8, 2004, and Japanese Patent Application No. 2005-234377, filed Aug. 12, 2005, the contents of which are incorporated by reference.

2. Description of Related Art

A method of manufacturing an electro-optic device has been realized which uses a droplet ejection method in which droplets are ejected on a substrate from an ink jet head, in order to form a thin film on the substrate. A display device such as a liquid crystal device, an organic electronic luminescent device (which will be called an organic EL device hereinafter), or a plasma display device is known as the electro-optic device.

In recent years, the substrate for an electro-optic device has been upsized and it is required to draw or pattern the thin film on the upsized substrate with high definition and high accuracy by using the droplet ejection method.

Such a droplet ejection method is known which adjusts theoretical ejecting positions of inks in accordance with the quantity of ink droplets per one ink ejection of an ejection head, in order to keep the quantity of inks ejected on each drawing target region constant (for example, refer to Japanese Patent Publication No. 3332812).

However, positions at which ink droplets land are not considered in each drawing target region, although it is considered to keep the quantity of selected inks constant in each drawing target region, according to the above-mentioned droplet ejection method.

Therefore, deviation occurs with respect to the landing positions of ink droplets in each drawing target region in the above-mentioned droplet ejection method. Alternatively, a slight unevenness develops with respect to the thickness of ink film which is ejected on each drawing target region. As a result, there is a concern of degradation in quality.

### SUMMARY OF THE INVENTION

The present invention was conceived in view of the above described circumstances and it is an object thereof to provide a droplet ejection method capable of ejecting ink droplets of appropriate quantity on a drawing target region without causing deviation with respect to a film thickness, in order to carry out drawing with high definition and high accuracy. Furthermore, it is another object of the present invention to provide a method of manufacturing an electro-optic device and an electronic instrument.

A first aspect of the present invention is a droplet ejection method of ejecting a droplet on a substrate, the droplet ejection method including: ejecting the droplet on a drawing target region surrounded by a bank formed on the substrate, in a predetermined ejecting interval while scanning an ejection head; and ejecting no droplet on a non-ejection area while scanning the ejection head, wherein the non-ejection area is located on the drawing target region except for a region along the bank in the drawing target region.

According to the first aspect of the present invention, swell having small depressions does not occur on a film surface along the bank, inasmuch as the non-ejection area on which no ink droplet is ejected is located at a central region of the drawing target region except for an outer region along the bank in the drawing target region, on ejecting an ink droplet on the drawing target region in a predetermined ejecting interval while scanning an ejection head. As a result, it is possible to thoroughly coat the ink droplet of appropriate quantity on the drawing target region and to form a film having an even film thickness. In other words, it is possible to eject the ink droplet of appropriate quantity in agreement with the drawing target region without causing deviation with respect to a film thickness and to carry out the drawing with high definition and high accuracy.

In the first aspect of the present invention, the drawing target region may be a rectangular region; and the non-ejection area may be located on the drawing target region except for a region along the bank in a direction of long sides of the drawing target region at least. Due to this, it is possible to reliably form the film having the even film thickness.

In the first aspect of the present invention, a plurality of non-ejection areas may be located on the drawing target region such that the plurality of non-ejection areas are spread. Due to this, it is possible to make the film thickness be more even.

In the first aspect of the present invention, the non-ejection area may be located on the drawing target region in parallel to the long sides of the drawing target region and may be located on the drawing target region except for the region along the bank in the direction of long sides of the drawing target region. Due to this, it is possible to reliably form the film having the even film thickness.

A second aspect of the present invention is a droplet ejection method of ejecting a droplet on a substrate, the droplet ejection method including: ejecting the droplet on a drawing target region surrounded by a bank formed on the substrate, in a predetermined ejection interval while scanning an ejection head; and ejecting the droplet on a different quantity area where the quantity of the droplet is different from the remaining one ejected on the other area of the drawing target region, while scanning the ejection head, wherein the different quantity area is located on the drawing target region except for a region along the bank in the drawing target region.

According to the second aspect of the present invention, it is possible to reliably form the film having the even film thickness.

In the second aspect of the present invention, the drawing target region may be a rectangular region; and the different quantity area may be located on the drawing target region except for a region along the bank in a direction of long sides of the drawing target region at least. Due to this, it is possible to reliably form the film having the even film thickness.

In the second aspect of the present invention, a plurality of different quantity areas may be located on the drawing target region such that the plurality of different quantity areas are spread. Due to this, it is possible to reliably form the film having the even film thickness.

Furthermore, the different quantity area may be located on the drawing target region in parallel to the long sides of the drawing target region and may be located on the drawing target region except for the region along the bank in the direction of long sides of the drawing target region. Due to this, it is possible to reliably form the film having the even film thickness.

A third aspect of the present invention is an electro-optic device manufacturing method that uses a droplet ejection method as recited above.

According to the third aspect of the present invention, it is possible to form a drawn pattern on a substrate with high definition, in order to manufacture an electro-optic device such as an organic EL device, a plasma display device, or a liquid crystal device. Therefore, it is possible to reduce the cost of the electro-optic device which is capable of displaying an image with high definition and high accuracy in all of large screen. Furthermore, it is possible to coat a substrate with a luminescent material and a hole transport material, each of which is a component of the organic EL device, with a high fine pixel pattern.

A fourth aspect of the present invention is an electronic instrument includes an electro-optic device manufactured by a method of the electro-optic device as recited above.

According the fourth aspect of the present invention, it is possible to reduce the cost of the electronic instrument capable of displaying an image with high definition and high accuracy. More specifically, it is possible to cheaply provide the electronic instrument capable of displaying an image of high quality.

### BRIEF DESCRIPTION OF THE DRAWINGS

FIG. 1 is a perspective view of a droplet ejection apparatus.

FIG. 2 is a block diagram showing the function of a control device used in the droplet ejection apparatus.

FIGS. 3A, 3B, and 3C are schematic plan views showing a map in the case in which a droplet ejection method of the present invention is not used, respectively.

FIGS. 4A and 4B are schematic plan views showing a map in the case in which a droplet ejection method of the present invention is used, respectively.

FIG. 5 is a schematic plan view showing a map in the case in which a droplet ejection method of the present invention is not used.

FIG. 6A and 6B are schematic plan view showing a map in the case in which a droplet ejection method of the present invention is used, respectively.

FIGS. 7A, 7B, 7C, and 7D are sectional views showing a manufacturing process for an organic EL device, respectively.

FIG. 8 is a circuit diagram of a display device manufactured by the manufacturing process.

FIG. 9 is an enlarged plan view showing a plane structure of a pixel region in the display device.

FIGS. 10A, 10B, and 10C are perspective views each showing an electronic instrument having the display device.

### DETAILED DESCRIPTION OF THE INVENTION

A description will be made as regards a droplet ejection method, a method of manufacturing an electro-optic device, and an electronic instrument according to embodiments of the present invention with reference to the drawings.

(Droplet Ejection Apparatus)

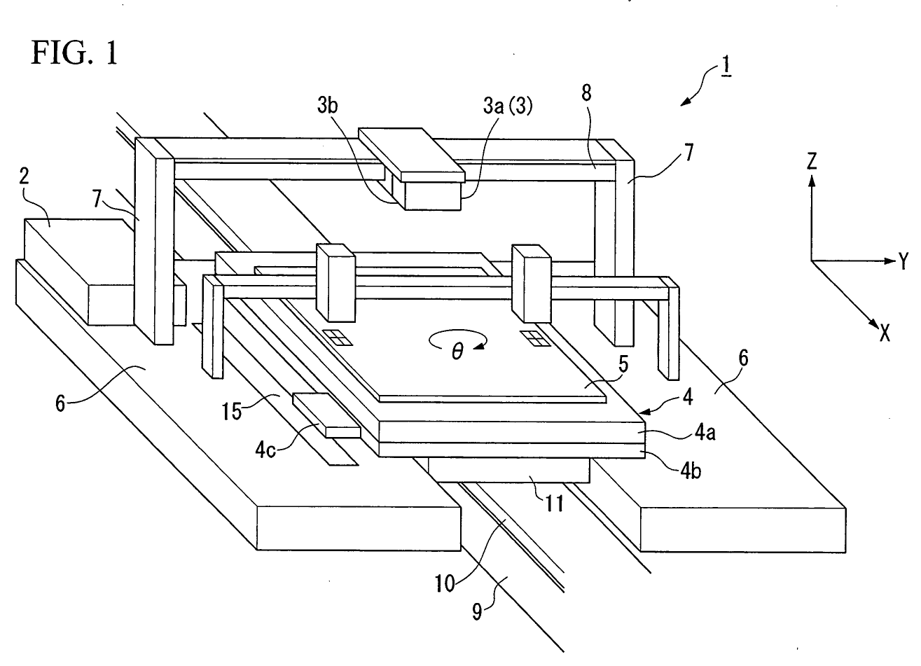

FIG. 1 shows a perspective view of the configuration of a droplet ejection apparatus;

The droplet ejection apparatus 1 is for use in a droplet ejection method according to the embodiment of the present invention. The droplet ejection apparatus 1 includes a control device 2 used as control means according to the present invention, an ejection head group 3, and a stage 4, as main components. In the droplet ejection apparatus 1, the control device 2 controls the ejection head group 3 and the stage 4 to eject droplets to a substrate 5 which is mounted on the stage 4, in order to form a predetermined pattern on the substrate 5.

The control device 2 controls the ejection head group 3 in accordance with the droplet ejection method according to the present invention, in order to control timing of droplet ejection. A camera 3b is fixedly attached to the ejection head group 3. The camera 3b is for use in carrying out an alignment and a positional compensation with respect to the substrate 5 mounted on the stage 4. The camera 3b is able to recognize an alignment mark which is formed on the substrate 5. In the description below, an X-axis represents an arrangement direction of the ejection head group 3. A Y-axis represents a direction in which the substrate 5 is transferred. A direction of in-plane rotation is represented by θ in an X-Y plane.

The ejection head group 3 is composed of a plurality of ejection heads 3a which are aligned in a row. An X-directional axis member 8 is positioned between supporting posts 7 which protrude upwards from a base member 6, so as to straddle the stage 4 in the X-axis direction. The ejection head group 3 is movably mounted on the X-directional axis member 8. The camera 3b, which is fixedly attached to the ejection head group 3, moves together with the ejection head group 3. A plurality of droplet ejecting nozzles, which are directed to the substrate 5 and which are for use in ejecting droplets, are formed on each of the ejection heads 3a of the ejection head group 3. For example, one hundred and eighty nozzles are formed on each of the ejection heads 3a in a row.

Each of the ejection heads 3a includes a cavity for storing liquid. The nozzles communicate with the cavity. Furthermore, each of the ejection heads 3a includes droplet ejection means for ejecting liquid stocked in the cavity as the droplets, from each of the nozzles. In the example being illustrated, the droplet ejection means may be, for example, a piezoelectric element which is mounted on a wall of the ejection head 3a. In the ejection head 3a having the above-mentioned configuration, the wall is strained or deformed in the ejection head 3a on the basis of a desirable voltage waveform supplied to the piezoelectric element so that the volume varies in the cavity and a predetermined amount of droplets are ejected from the nozzles. The voltage waveform supplied from the piezoelectric element is produced in accordance with droplet ejecting data which will be described hereinafter.

Incidentally, it is possible to adopt a method using an electro-thermal transducer as an energy generating element, a continuous method such as a charge control or a pressurized vibration, an electrostatic suction method, or a method of ejecting liquid by an operation based on radiation heat of electromagnetic waves such as a laser, instead of the method using the piezoelectric element (electromechanical transducer) as the droplet ejection means for the ejection heads 3a.

Although the ejection head group 3 is composed of a plurality of ejection heads 3a which are aligned in a row in the illustrated example, the ejection head group 3 is not limited by the illustrated example. For example, the ejection heads 3a may be aligned in two rows in which the nozzles are shifted ½ pitch in the X-axis direction with respect to a nozzle space (nozzle pitch). Alternatively, each of the ejection heads 3a may be aligned at a predetermined angle with respect to the X-axis direction. By the above-mentioned configuration of the ejection head group, it is possible to eject the droplets with a small space which is less than the nozzle space.

The stage 4 includes a setting section 4a on which the substrate 5 is set, and a base section 4b for rotatably supporting the setting section 4a in the X-Y plane. The setting section 4a has locating pins (not shown) or the like. The base section 4b has an encoder 4c. The encoder 4c reads a linear scale 15 which is positioned along the Y-axis direction of a base member 6, in order to detect the position of the stage 4 in the Y-axis direction in accordance with the read result. The linear scale 15 may be in metric. Alternatively, the linear scale 15 may be in dpi (dots per inch).

Furthermore, the stage 4 can move along a Y-axis member 9 which is perpendicular to the X-axis direction. In the example being illustrated, a linear motor is used as a transferring mechanism for making the stage move along the Y-axis direction. The linear motor includes permanent magnets 10 arranged on the Y-axis member 9, and a plurality of coils (not shown) which are fixedly mounted below the base section 4b of the stage 4. The coils are arranged along the Y-axis direction and on a plate 11 near the permanent magnets 10.

The substrate 5 is an object on which a pattern is formed in the present embodiment. Although a transparent substrate such as a glass substrate is generally used as the substrate 5, a metal plate may be used as the substrate 5 in the case in which transparency is not required. In addition, the substrate 5 may have a size whose length and width are greater than 1 m, respectively.

The pattern formed on the substrate 5 may be, for example, a pixel pattern formed by a color filter having RGB colors, or a metal wiring pattern for use in forming a TFT circuit.

More particularly, the pixel pattern composed of a luminescent material or a hole transport material is formed by the present droplet ejection apparatus 1 in the case of manufacturing an organic EL device by using the substrate 5.

The control device 2 is electrically connected to each component of the droplet ejection apparatus 1. The control device 2 is a so-called computer having a CPU (Central Processing Unit), a ROM, a RAM, an inputting and outputting interface, and an oscillation circuit all of which are connected to one another by a bus. Such a control device 2 controls the droplet ejection apparatus 1 on the basis of programs which are inputted in advance.

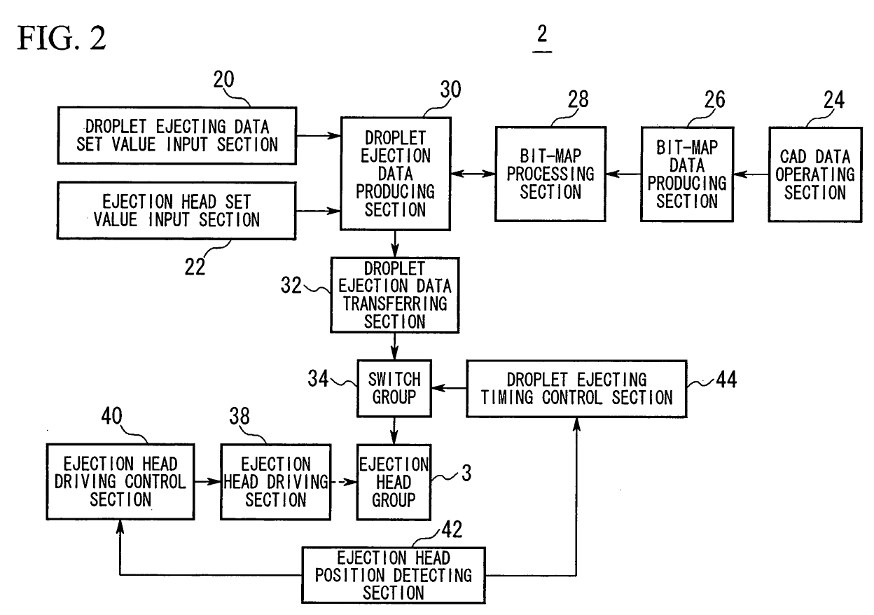

Next, a description will proceed as to a detailed configuration of the control device 2 with reference to FIG. 2. FIG. 2 is a block diagram for describing a function of the control device 2.

The control device 2 includes an droplet ejecting data set value input section (first inputting means) 20, an ejection head set value input section (second inputting means) 22, a CAD data operating section (CAD data producing means) 24, a bit-map data producing section (bit-map data producing means) 26, a bit-map processing section 28, a droplet ejecting data producing section (producing means) 30, a droplet ejecting data transferring section (transferring means) 32, a switch group 34, a head driving section 38, a head drive controlling section 40, a head position detecting section 42, and a droplet ejecting timing control section 44. The droplet ejecting timing control section 44 is for changing a timing in which the droplet is ejected.

The droplet ejecting data set value input section 20 has functions for establishing the size of substrate 5, the size of each chip in the case in which the substrate 5 is cut into a plurality of chips (regions), a pitch (mutual space) between adjacent chips, the alignment of pixels (pattern), the number of pixels, the size (length and width) of each pixel, and a pitch (mutual space) between adjacent pixels. The ejection head set value input section 22 has functions for establishing a necessary amount of a droplet for forming the pixels, the necessary number of paths (the number of relative transferring operations) between the ejection head group 3 and the substrate 5 in the case of forming the pixels, the number of ejection heads 3a of the ejection head group 3 to be used, and the locations of the ejection heads 3a.

The CAD data operating section 24 has a function for producing CAD data which becomes a design drawing of pattern formed on the substrate 5. The CAD data operating section 24 includes input means for inputting graphic information (for example, vector data and data such as attribute data of graphics) and a work station having a graphics processing function. The CAD data may be produced in metric. Alternatively, the CAD data may be produced in dpi (dots per inch).

The bit-map data producing section 26 has a function for converting original data into bit-map data having a resolution that is required by the CAD data. The bit-map processing section 28 changes the bit-map data produced by the bit-map producing section 26, in accordance with a requirement for a fine circuit pattern, taking the number of ejection heads 3a, the locations of ejection heads 3a, and the landing diameter of a droplet on the substrate 5 into consideration.

The droplet ejecting data producing section 30 is for producing droplet ejecting data (binary time-series data) so as to make a pattern having a desirable pattern size, taking the diameter of a landed droplet into consideration on landing the droplet on the substrate 5. Incidentally, the droplet ejecting data includes record data representative of dot numbers which correspond to the number of droplet ejection means mounted in correspondence to the nozzles of the ejection head group 3.

The droplet ejecting data transferring section 32 has a function for transferring the droplet ejecting data outputted from the droplet ejecting data producing section 30, to the droplet ejection means of the ejection head group 3. The switch group 34 includes a plurality of switches which are positioned between the droplet ejecting data transferring section 32 and the ejection head group 3. The switches are connected to a plurality of driving sections included in the ejection head group 3, in a one-to-one relationship. Responsive to the record data transferred from the droplet ejecting data transferring section 32, the switches are selectively set into an on-state or an off-state.

The ejection head driving section 38 is integral with the ejection head group 3 and may be, for example, a linear motor. The ejection head driving section 38 makes the ejection head group 3 move in a direction perpendicular to the transferring direction of the substrate 5. The ejection head driving control section 40 controls the head driving section 38 in accordance with instructions supplied from a host controller of a system which is not illustrated.

The ejection head position detecting section 42 has a function for detecting the quantity of displacement with respect to the location of the stage 4 on which the substrate 5 is fixed or mounted, that is, for detecting a relative location between the ejection head group 3 and the substrate 5. The ejection head position detecting section 42 may be, for example, the above-mentioned encoder 4c. The droplet ejecting timing control section 44 produces a latch signal (LAT signal) defining timing at which the voltage waveform is generated which is supplied to the piezoelectric element of each ejection head, in accordance with detection results obtained by the ejection head position detecting section 42, in order to output the LAT signal. The LAT signal is delivered to the switch group 34. Each switch of the switch group 34 is selectively controlled to the on-state or the off-state on the basis of the LAT signal and the droplet ejecting data supplied from droplet data transferring section 32. Furthermore, driving timing is controlled in the piezoelectric element of each ejection head 3a by each switch, in order to control the droplet ejecting timing in each ejection head 3a.

Next, a description will proceed as to the droplet ejection method of ejecting the droplet by using the droplet ejection apparatus 1 according to the present embodiment. The droplet ejection is mainly carried out by the droplet ejecting timing control section 44 of the droplet ejection apparatus 1.

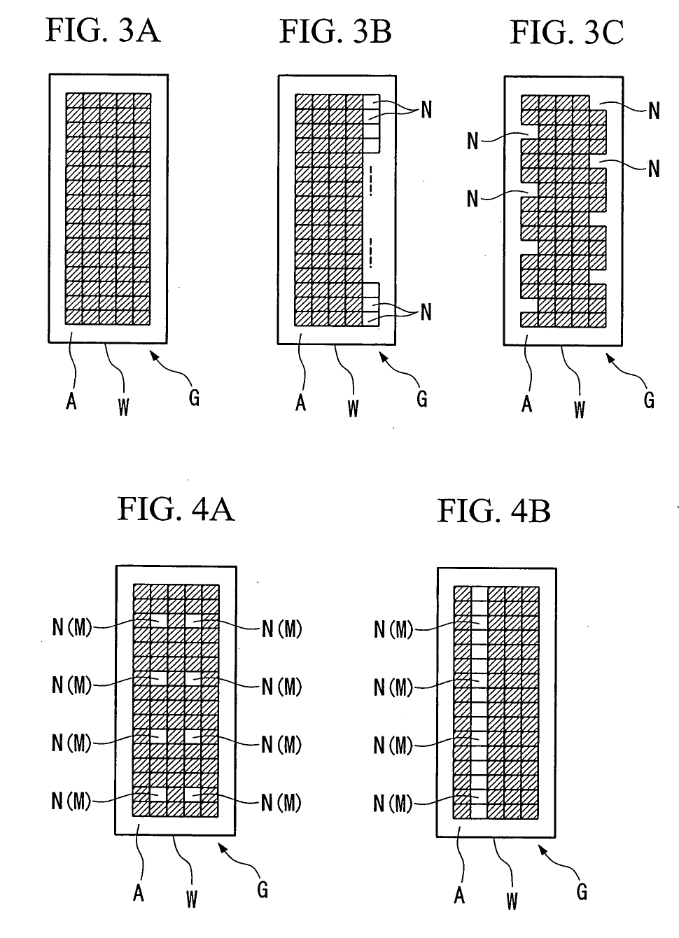

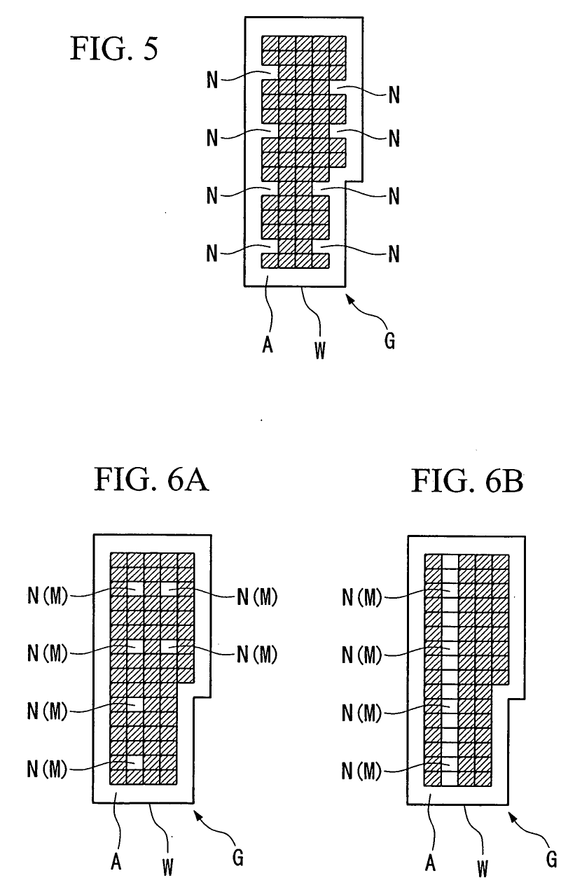

FIGS. 3A, 3B, and 3C and FIG. 5 show schematic plan views of maps illustrating ejected states in the case in which the droplet ejection method according to the present invention is not used. FIGS. 4A and 4B and FIG. 6A and 6B show schematic plan views of maps for illustrating ejected states in the case in which the droplet ejection method according to the present invention is used.

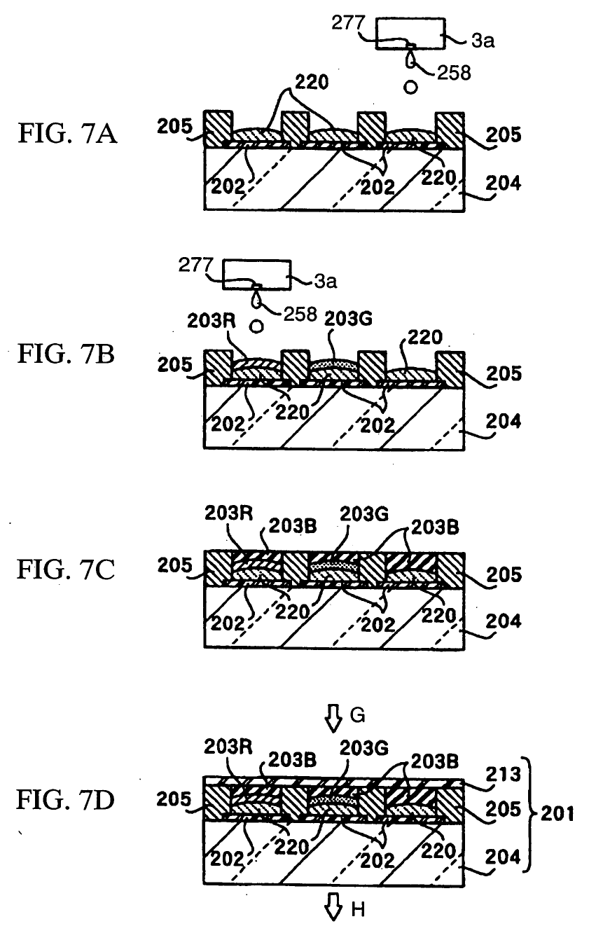

The droplet ejection apparatus 1 ejects the droplet at an ejecting timing in a predetermined ejecting interval while scanning the ejection head 3a in one direction with respect to a pixel G which is a drawing object to be formed on the substrate 5. As a result, the droplets land on a drawing target region A on which the pixel G is formed and which is surrounded by a bank (which is not shown in the illustrated example and will be referred to in FIG. 7), in accordance with bit-map data.

Incidentally, each ejection head 3a ejects a predetermined quantity of droplets in one ejection. When landing the droplets on the whole area of the pixel G at all of the ejecting timings in which the droplets are ejected on the drawing target region A, as shown in FIG. 3A, it easily occurs that droplets become excessive or lacking in quantity. In the case in which the droplets are excessive in quantity, it is necessary to adjust the quantity of droplets in a drawing target region A. For example, the quantity of ejected droplets is reduced in each ejection at a predetermined ejecting timing or the remaining droplets are ejected without ejecting a part of the droplets, in order to adjust the quantity of droplets in the drawing target region A.

In the case in which the remaining droplets are landed on the pixel G without ejecting a part of the droplets, the quantity of droplets becomes small in non-ejection areas N in which no droplet is ejected, and a bias occurs in the film thickness, when biasing the non-ejection areas N to one side of the drawing target region A as shown in FIG. 3B.

Although the droplets are spread in an appropriate quantity when the non-ejection areas N are spread along a bank which forms the drawing target region A as shown in FIG. 3C, swelling caused by small depressions easily occurs on a film surface which is formed along the bank after the droplets have landed.

Under these circumstances, production is made about the bit-map data having the non-ejection areas N at a central region in the drawing target region A except for an outer region along the bank, as shown in FIG. 4A, in the droplet ejection method according to the present invention. In the case in which there are a plurality of non-ejection areas N, it is preferable to locate the non-ejection areas N such that they are spread. Inasmuch as the non-ejection areas N are spread at the central region in the drawing target region A except for the outer region along the bank, a droplet is thoroughly coated on the drawing target region A in the appropriate quantity. As a result, it is possible to form the pixel G having an even film thickness.

Alternatively, production may be made about the bit-map data having the non-ejection areas N at a central region in the drawing target region A except for an outer region along the bank in the direction of at least long sides of the drawing target region A, as shown in FIG. 4B. The non-ejection areas N may be located on the outer region along the bank in the direction of short sides of the drawing target region A. For example, a row or a plurality of rows, which are approximately parallel to the direction of long sides of the bank and which are located on a central region of the drawing target region A, are used as the non-ejection areas N in ejection areas (bit-map data producing section) located on the drawing target region A in a grid shape. When locating the rows of non-ejection areas which are aligned along the long sides of the bank in the drawing target region A, swelling hardly occurs in a film surface after the droplets have landed onto the drawing target region A. It is possible to easily produce the bit-map data and to control ejecting of the droplets without a complex operation.

Incidentally, a phenomenon in which the swell occurs on the film surface formed after the droplets have landed is not limited in the case in which the drawing target region A has a rectangular shape in plan view, but the phenomenon occurs in the case in which the non-ejection areas N are located along the bank with respect to a region having an outer shape shown in FIG. 5.

In this case, it is possible to make the film thickness, uniform in the film formed after the droplets have landed, when the non-ejection areas N are spread in the central region of the drawing target region except for the outer region along the bank in the drawing target region A as shown in FIG. 6A and 6B.

As described above, swelling having small depressions does not occur on the surface of a film formed along the bank, after the droplets have landed, inasmuch as the non-ejection areas N on which no droplet is ejected are located at the central region of the drawing target region except for the outer region along the bank in the drawing target region A. As a result, it is possible to thoroughly apply the droplets of appropriate quantity on the drawing target region A and to make the film thickness uniform.

In other words, it is possible to land the droplets of appropriate quantity in agreement with the drawing target region A without causing a deviation with respect to a film thickness and to carry out the drawing with high definition and high accuracy.

In addition, it is possible to make the film thickness more uniform, inasmuch as the non-ejection areas N are spread in the central region of the drawing target region A except for, the outer region along the bank in the drawing target region A.

Incidentally, it is possible to adjust the quantity of droplets ejected onto the drawing target region A when each of the non-ejection areas N (different quantity area M) is supplied with droplets whose quantity is less than that of each ejection area, although the non-ejection areas are located on the drawing target region N in the method of adjusting the quantity of droplets in the drawing target region A. Using the different quantity area M, swelling hardly occurs on the surface of a film formed in the drawing target region A in comparison to the non-ejection areas onto which no droplet is ejected.

Furthermore, each of the non-ejection areas N described above (different quantity area M) is supplied with droplets whose quantity is greater than that of each ejection area, in order to adjust the quantity of droplets in the drawing target region A in the case in which the quantity of droplets is small in the drawing target region A. In addition, it is possible to adjust the quantity of droplets by a combination of not ejecting the droplets, ejecting the droplets in a small quantity, and ejecting the droplets in large quantity.

(Electro-Optic Device)

Next, a description will proceed as to an example of electro-optic device manufactured by using the above-mentioned droplet ejection method, with reference to the drawings. In the present embodiment, an organic EL device will be described as an example of the electro-optic device.

FIGS. 7A, 7B, 7C, and 7D show main sectional views illustrating manufacturing processes of the organic EL device according to an embodiment of the present invention.

As shown in FIG. 7D, an organic EL device 201 has a structure in which pixel electrodes 202 are formed on a transparent substrate 204 and banks 205 are located between the pixel electrodes 202 in a grid shape in the case of looking in a direction of an arrow G.

Hole injection layers 220 are formed in grid shaped concave regions each of which is the drawing target region A. A luminescent layer 203R of R color, a luminescent layer 203G of G color, and a luminescent layer 203B of B color are formed in the grid shaped concave regions, so as to be arranged in a predetermined array such as a strip array in the case of looking in a direction of the arrow G Furthermore, opposed electrodes 213 are formed on the luminescent layers 203R, 203G, and 203B.

In the case of driving the pixel electrodes 202 by a two-terminal active element such as a TFD (Thin Film Diode), the opposed electrodes 213 are formed in a strip shape on looking in a direction of the arrow G On the other hand, the opposed electrodes 213 are formed as a single plane electrode in the case of driving the pixel electrodes 202 by a three-terminal active element such as a TFT (Thin Film Transistor).

A region interposed between the pixel electrodes 202 and the opposed electrodes 213 corresponds to a picture element. The picture elements of three colors R, G, and B become one unit in order to form one pixel.

The picture elements selectively emit light by controlling a current flowing through each picture element. As a result, it is possible to display a desired full-color image in a direction of an arrow H.

The above-mentioned organic EL device is manufactured by a manufacturing method described hereinafter. As shown in FIG. 7A, the active elements such as TFD elements or TFT elements are formed on the surface of the transparent substrate 204 and the pixel electrodes 202 are formed on the transparent substrate 204. On forming the pixel electrodes 202, it is possible to use photolithography, vacuum evaporation, sputtering, pyrosol or the like.

It is possible to use ITO (Indium-Tin Oxide), tin oxide, or a compound oxide composed of indium oxide and zinc oxide, as a material of each pixel electrode 202.

As shown in FIG. 7A, barriers, that is to say, the banks 205 are formed using a known patterning method, for example, a photolithography method, in order to fill the banks 205 in the boundaries between the transparent pixel electrodes 202. As a result, it is possible to improve contrast and to prevent color mixture in luminescent materials. Furthermore, it is possible to prevent light leakage between pixels. Although each of the banks 205 is not limited in material in the case where the banks 205 have durability with respect to a solvent which is included in the EL luminescent material, it is preferable that the material be capable of being processed into Teflon® by fluorocarbon gas plasma treatment. For example, it is preferable to use an organic material such as acrylic resin, epoxy resin, or photosensitive polyimide, as the material of banks 205.

Just before coating a material for a hole injection layer that is a functional liquid form, a continuous plasma treatment is carried out with respect to the transparent substrate 204 by using oxygen gas and fluorocarbon gas plasma. As a result, a liquid repellency is imparted to the polyimide surface and a liquid affinity is imparted to the ITO surface. In other words, wettability is controlled in the substrate in order to carry out a fine patterning by using droplets. It is possible to use an apparatus for generating the plasma in a vacuum or an apparatus for generating the plasma in air, as an apparatus for generating the plasma.

As shown in FIG. 7A, a droplet 258, which is the material for the hole injection layer, is ejected from the ejection head 3a of the droplet ejection apparatus 1 illustrated in FIG. 1, in order to carry out a pattern coating. The droplet 258 is ejected in accordance with the droplet ejection method according to the present invention. Accordingly, the droplet 258 correctly lands on the ejection region, that is to say, a filter element forming region which is a desired drawing target region surrounded by bank 205. The droplet is applied on the filter element forming region with a uniform thickness. After coating, the substrate is kept at room temperature for 20 minutes in a vacuum (1 torr), in order to remove the solvent from the substrate. After that, the substrate is subjected to a heat treatment at a temperature of 200° C. (on a hot plate) in air, in order to form the hole injection layers 220 each of which is not compatible to the material for a luminescent layer, on the substrate. In the above-mentioned conditions, each of the hole injection layers 220 has a thickness of 40 nm.

As shown in FIG. 7B, a material for an R luminescent layer and a material for a G luminescent layer each of which is a functional liquid form used as an EL luminescent material are coated on the hole injection layer 220 positioned in each filter element forming region. Each material for the luminescent layer is ejected as a droplet 258 from the ejection head 3a of the droplet ejection apparatus 1 illustrated in FIG. 1 and lands on each filter element forming region. Inasmuch as the droplet 258 is ejected on the basis of the droplet ejection method according to the present invention, each droplet 258 lands on each filter element forming region and is applied on the filter element forming region with a uniform thickness.

After applying each material for the luminescent layer, the substrate is kept at room temperature for 20 minutes in a vacuum (1 torr), in order to remove the solvent from the substrate. Furthermore, the substrate is subjected to a heat treatment at a temperature of 150° C. for 4 hours in a nitrogen atmosphere, in order to carry out conjugation and to form the R color luminescent layer 203R and the G color luminescent layer 203G. In the above-mentioned conditions, each of the R color luminescent layer 203R and the G color luminescent layer 203G has the thickness of 50 nm. The luminescent layer conjugated by the heat treatment is insoluble in the solvent.

Incidentally, each of the hole injection layers 220 may be subjected to a continuous plasma treatment using oxygen gas and fluorocarbon gas plasma, before forming the luminescent layers. In the case of carrying out the continuous plasma treatment, a fluorine compound layer is formed on each of the hole injection layers 220. As a result, ionization potential becomes high and efficiency increases with respect to the hole injection. It is possible to provide the organic EL device having a high luminescent efficiency.

As shown in FIG. 7C, a material for the B luminescent layer 203B which is a functional liquid form used as an EL luminescent material is formed on the R color luminescent layer 203R, the G color luminescent layer 203G, and the hole injection layer 220 in each picture element. As a result, formation is made about three primary colors of R, G, and B and it is possible to become flattened by filling in steps between the R color luminescent layer 203R and the G color luminescent layer 203G and the bank 205. In addition, it is possible to reliably prevent shortage occurring between an upper electrode and a lower electrode. When adjusting the thickness of the B color luminescent layer 203B, the B color luminescent layer 203B acts as an electron injection transport layer and does not emit light in a laminated structure of the R color luminescent layer 203R and the G color luminescent layer 203G.

More particularly, it is possible to adopt a general spin-coat method as a wet process on forming the B color luminescent layer 203B described above. Alternatively, it is possible to adopt an ink-jet method which is similar to a method for use in forming the R color luminescent layer 203R and the G color luminescent layer 203G, on forming the B color luminescent layer 203B.

As shown in FIG. 7D, the organic EL device 201 is manufactured by forming the opposed electrode 213. In the case in which the opposed electrode 213 is the plane electrode, Mg, Ag, Al, or Li is used as a material for the opposed electrode 213 and the opposed electrode 213 is formed by using a film forming method such as an evaporating method or a sputtering method. In the case in which the opposed electrode 213 is a stripe-shaped electrode, it is possible to process a deposited electrode layer into the opposed electrode 213 by using a patterning method such as a photolithography method.

According to the method of manufacturing the organic EL device described above, the droplet 258 is ejected from the ejection head 3a of droplet ejection apparatus 1 illustrated in FIG. 1, with respect to each of the material for the hole injection layer and the materials for the luminescent layers, and it is possible for each material to land in each filter element forming region. Therefore, the material for the hole injection layer or each material for the luminescent layer is applied in the bank 205 with uniform thickness and without unevenness. As a result, it is possible to easily manufacture the organic EL device having a large screen that is capable of displaying an image having high definition and high quality, over the whole screen, according to the present manufacturing method.

In addition, it is unnecessary to undergo a complex process like the method using photolithography and it is possible to prevent the materials from being wasted, inasmuch as the picture elements of R, G, and B are formed by the droplets which are ejected from the ejection head 3a of the droplet ejection apparatus 1, in the method of manufacturing the organic EL device according to the present embodiment.

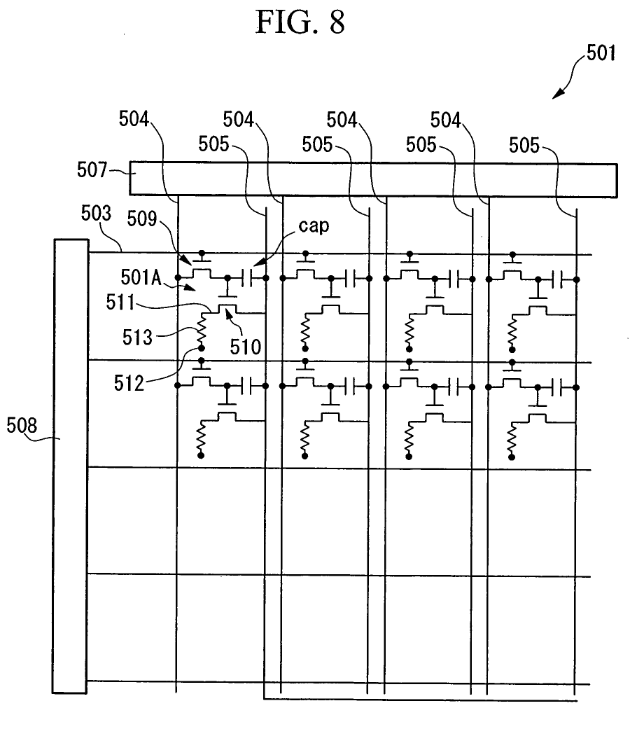

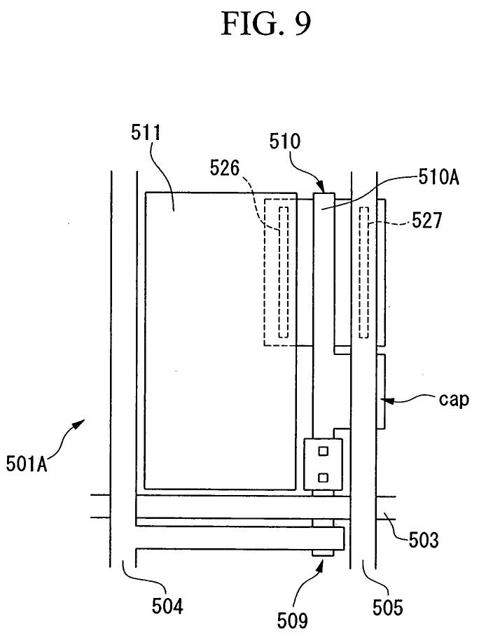

Next, a description will proceed as to a circuit configuration of the organic EL device according to the present embodiment, with reference to FIGS. 8 and 9.

FIG. 8 shows a view illustrating a part of a display device having the organic EL device as a component that is manufactured by the manufacturing method illustrated in FIG. 7A to FIG. 7D. FIG. 9 shows an enlarged plan view illustrating a plan structure of a pixel region in the display device illustrated in FIG. 8.

In FIG. 8, a display device 501 is an active matrix type display device using an EL display element which is the organic EL display device. The display device 501 has a structure in which a plurality of scanning lines 503, a plurality of signal lines 504, and a plurality of common electric supply lines 505 are wired on a transparent substrate 502. The signal lines 504 extend in a direction in which the signal lines 504 intersect the scanning lines 502. The common electric supply lines 505 extend in a direction in which the common electric supply lines 505 are parallel to the signal lines 504. A pixel region 501A is located on each point of intersection of the scanning lines 503 and the signal lines 504.

A data driving circuit 507, which has shift registers, level shifters, video lines, and analog switches, is connected to each of the signal lines 504. A scan driving circuit 508, which has shift registers and level shifters, is connected to each of the scanning lines 503. A switching thin film transistor 509, a storage capacitor cap, a current thin film transistor 510, a pixel electrode 511, and a luminous element 513 are located on each pixel region 501A. A scanning signal is supplied to the gate electrode of the switching thin film transistor 509 through the scanning line 503. The storage capacitor cap stores an image signal supplied from the signal line 504 through the switching thin film transistor 509. The image signal stored in the storage capacitor cap is supplied to the gate electrode of the current thin film transistor 510. The pixel electrode 511 is supplied with a driving current from common electric supply lines 505, when the pixel electrode 511 is electrically connected to the common electric supply lines 505 through the current thin film transistor 510. The luminous element 513 is interposed between the pixel electrode 511 and the opposed electrode 512.

According to the above-mentioned configuration, the electric potential on the signal line 504 is held in the storage capacitor cap when the scanning line 503 is driven and the switching thin film transistor 509 is switched to the on-state. On the basis of the state of the storage capacitor cap, either one of the on-state and the off-state is determined in the current thin film transistor 510. Current passes from the common electric supply line 505 to the pixel electrode 511 through the channel of the current thin film transistor 510. Furthermore, current passes to the opposed electrode 512 through the luminous element 513.

As a result, the luminous element 513 emits light in accordance with the amount of current passing to the luminous element 513.

As shown in FIG. 9 which is an enlarged plan view of the display device 501 in a condition of omitting the opposed electrode 512 and the luminous element 513, the pixel electrode 511 has a rectangular shape in plan view whose four sides are surrounded by the signal line 504, the common electric supply line 505, the scanning line 503, and the scanning line 503 for another pixel electrode 511 that is not illustrated, in the pixel region 501A.

Inasmuch as the display device 501 having the above configuration is manufactured by using the method of manufacturing the organic EL device, the display device is comparatively cheap and can display an image having high definition and high quality over the whole screen.

(Electronic Instrument)

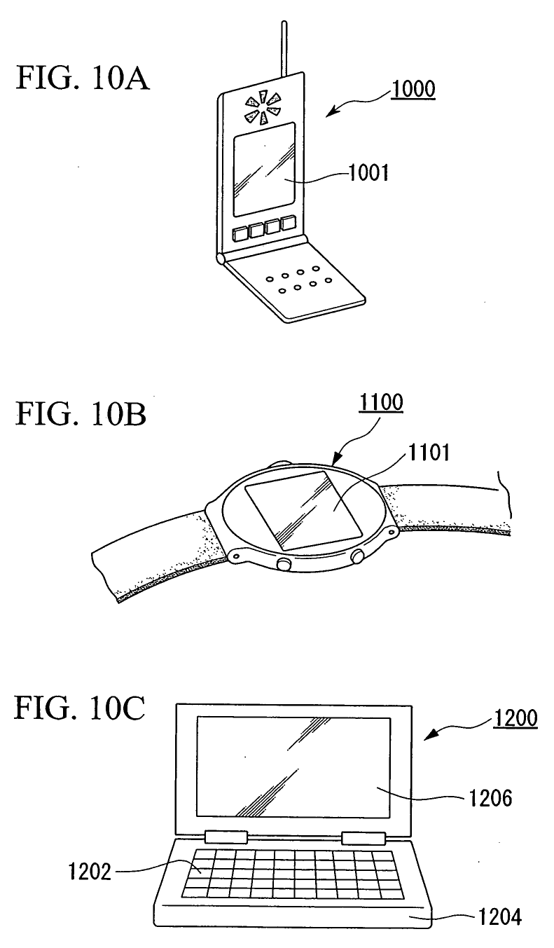

A description will proceed as to an electronic instrument having the electro-optic device described in the above-mentioned embodiment. FIG. 10A shows a perspective view illustrating an example of a mobile phone.

In FIG. 10A, a reference numeral 1000 represents a mobile phone main body. A reference numeral 1001 represents a display section composed of the electro-optic device according to the present embodiment.

FIG. 10B shows a perspective view illustrating an example of a wrist watch type electronic instrument. In FIG. 10B, a reference numeral 1100 represents a watch main body. A reference numeral 1101 represents a display section composed of the electro-optic device according to the present embodiment.

FIG. 10C shows a perspective view for illustrating an example of man-portable information processing equipment such as a word processor, a personal computer, or the like. In FIG. 10C, a reference numeral 1200 represents information processing equipment. A reference numeral 1202 represents an input section such as a keyboard. A reference numeral 1204 represents an information processing equipment main body. A reference numeral 1206 represents a display section composed of the electro-optic device according to the present embodiment.

Inasmuch as the electronic instrument illustrated in each of FIG. 10A, 10B, and 10C has the electro-optic device according the above-mentioned embodiment, it is possible to display an image having high definition and high quality even if the display section has a large screen.

Incidentally, the present invention is not limited in a technical range to the above-mentioned embodiment. It is possible to add variations without departing from the scope of the present invention. In addition, the materials and the layer structure described in the embodiment are mere examples and it is possible to properly apply variations. More specifically, the present invention is not limited to the organic EL device although the organic EL device is described as an example of electro-optic device in the above-mentioned embodiment. The present invention is applicable to an electro-optic device such as a plasma display device, a liquid crystal device, or the like. Furthermore, the present invention is applicable to applying a coloring material to a color filter. In addition, it is possible to form a wiring pattern, an electrode, or a type of semiconductor by using the droplet ejection method according to the present invention without the droplet ejection method according to the present invention being limited to formation of pixels.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A droplet ejection method of ejecting a droplet on a substrate, comprising:
ejecting the droplet on a drawing target region surrounded by a bank formed on the substrate, in a predetermined ejection interval while scanning an ejection head; and
ejecting no droplet on a non-ejection area while scanning the ejection head, wherein
the non-ejection area is located on the drawing target region except for a region along the bank in the drawing target region.

2. A droplet ejection method according to claim 1, wherein
the drawing target region is a rectangular region, and
the non-ejection area is located on the drawing target region except for a region along the bank in a direction of long sides of the drawing target region at least.

3. A droplet ejection method according to claim 1, wherein
a plurality of non-ejection areas are located on the drawing target region such that the plurality of non-ejection areas are spread.

4. A droplet ejection method according to claim 2, wherein the non-ejection area is located on the drawing target region in parallel to the long sides of the drawing target region and is located on the drawing target region except for the region along the bank in the direction of long sides of the drawing target region.

5. A droplet ejection method of ejecting droplet on a substrate, comprising:
ejecting the droplet on a drawing target region surrounded by a bank formed on the substrate, in a predetermined ejection interval while scanning an ejection head; and
ejecting the droplet on a different quantity area where the quantity of the droplet is different from the remaining one ejected on the other area of the drawing target region, while scanning the ejection head, wherein
the different quantity area is located on the drawing target region except for a region along the bank in the drawing target region.

6. A droplet ejection method according to claim 5, wherein
the drawing target region is a rectangular region, and
the different quantity area is located on the drawing target region except for a region along the bank in a direction of long sides of the drawing target region at least.

7. A droplet ejection method according to claim 5, wherein
a plurality of different quantity areas are located on the drawing target region such that the plurality of different quantity areas are spread.

8. A droplet ejection method according to claim 6, wherein the different quantity area is located on the drawing target region in parallel to the long sides of the drawing target region and is located on the drawing target region except for the region along the bank in the direction of long sides of the drawing target region.

9. An electro-optic device manufacturing method that uses a droplet ejection method according to claim 1.

10. An electro-optic device manufacturing method that uses a droplet ejection method according to claim 5.

11. An electronic instrument comprising an electro-optic device manufactured by a method of the electro-optic device according to claim 9.

12. An electronic instrument comprising an electro-optic device manufactured by a method of the electro-optic device according to claim 10.
